(19) United States
(12) Patent Application Publication
(10) Pub. No.: US 2016/0052717 A1
(43) Pub. Date: Feb. 25, 2016

(54) BELT FOR A CONVEYOR UNIT

(71) Applicant: VIT, Saint-egreve (FR)

(72) Inventor: Christian WOLF, Saint Egreve (FR)

(21) Appl. No.: 14/779,063

(22) PCT Filed: Mar. 26, 2014
(86) PCT No.: PCT/FR2014/050709

§ 371 Date: Sep. 22, 2015

(30) Foreign Application Priority Data
Mar. 28, 2013 (FR) 1352822

(51) Int. Cl. B65G 15/12; H05K 13/00; B65G 15/32

(52) U.S. Cl. CPC B65G 15/12; B65G 15/32; H05K 13/0061

(57) ABSTRACT

A conveyor unit has a conveyor belt comprising, in cross-section, a recess in the upper edge of the belt. In an embodiment, the unit comprises two belts that support the objects to be transported, in particular electronic boards.

### BACKGROUND

The present disclosure generally relates to industrial units and, more particularly, to a belt conveyor unit, for objects having a generally planar shape.

An example of application of the present disclosure relates to units for processing, for example, optically, electronic boards.

### DISCUSSION OF THE RELATED ART

In electronic board optical processing units, boards are generally automatically displaced by a belt system. More specifically, plates rest on two of their opposite edges on flat transport belts which are driven in the conveying direction of the unit. The belt is partially housed in a guide groove which only lets laterally protrude a portion of its upper surface, intended to receive the object to be conveyed. However, due to inevitable mechanical tolerances at the belt housing level, one edge of the board may get caught into the groove, particularly in the case where very thin boards, for example, of less than 0.5 mm, are conveyed, which adversely affects the operation of the unit and may damage the processed board.

Document WO 2010/049869 describes a conveyor unit comprising vertical belts having shoulders supporting an object.

### SUMMARY

An embodiment aims at overcoming all or part of the disadvantages of usual belt conveyor systems.

An embodiment aims at providing a belt conveyor system more particularly intended for planar objects or objects having planar edges, relatively thin as compared with the necessary clearances of the unit.

An embodiment aims at providing a lateral positioning of the objects relative to the conveying direction.

Thus, different embodiments of a conveyor unit such as defined in the claims are provided.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a very simplified top view of a conveyor unit of the type to which the embodiments which will be described apply;

FIG. 1A illustrates a detail of a usual unit;

FIG. 2 is a very simplified representation of a lateral view of an example of a conveyor unit;

FIG. 3 is a perspective view showing an embodiment of a belt;

FIG. 4 is a transverse cross-section view illustrating an embodiment of a belt and the relative positioning of a conveyed object;

FIGS. 5 and 6 are transverse cross-section views of the two rollers of FIG. 3;

FIG. 7 is a perspective cross-section view of an enlargement of FIG. 3; and

FIG. 8 is a partial perspective transverse cross-section view of an alternative belt.

### DETAILED DESCRIPTION

The same elements have been designated with the same reference numerals in the different drawings. For clarity, only those steps and elements which are useful to the understanding of the described embodiments have been shown and will be detailed. In particular, the destination of the conveyor unit has not been detailed, the described embodiments being compatible with usual applications of conveyor units. Further, the planar objects, for example, the boards supporting electronic circuits, have not been detailed either, the described embodiments being here again compatible with the rest of the elements of usual units for conveying such objects. Further, unless otherwise specified, terms relative to position and orientation such as “top”, “bottom”, “upper”, “lower”, “front”, “back”, “left”, “right”, etc. refer to elements in their normal position of use in the unit and in the normal direction of forward movement of the conveyor. Further, when exact dimensions are mentioned, they should be understood to within manufacturing tolerances and when the dimensions are indicated as being approximate, they should be understood to within +/−10%.

The embodiments are described in relation with an example applied to an electronic board conveyor unit or equipment. They however more generally apply to any planar object or object having planar edges, where the lateral positioning is desired to be performed by means of the object itself.

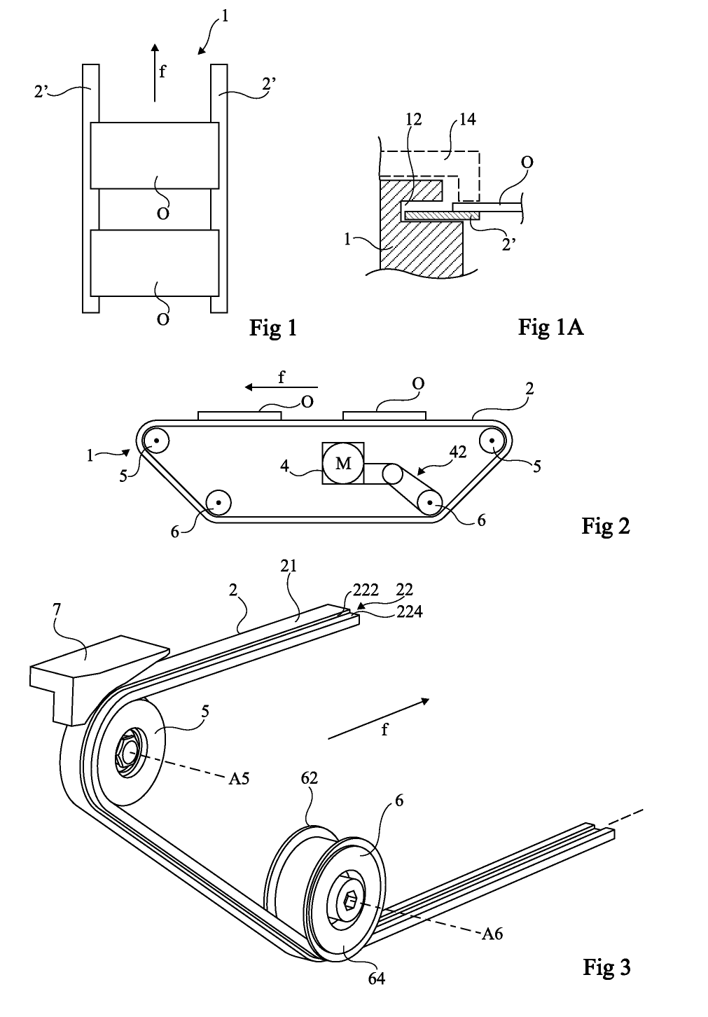

FIG. 1 is a very simplified top view of an example of electronic board conveyor unit (supporting electronic components), for example, in optical inspection equipment. The boards are laid on a conveyor comprising, in this example, two looped belts 2′ parallel to the conveyor direction.

FIG. 1A is a partial cross-section view illustrating a detail of unit 1 at the level of belt 2′ which is, conventionally, a flat belt having a rectangular cross-section. In the conveying area, that is, in the portion of the unit where objects O are laid, by their edges, on belt 2′, the latter is housed in a guide groove 12 and object O then only rests on a portion of belt 2′.

In the case of objects having relatively thin edges as compared with the height of groove 12, these edges risk engaging into groove 12. The objects then risk being damaged. At least, this adversely affects their positioning in the conveyor unit, which may be particularly disturbing in the case where the positioning of the object conditions the rest of the operations implemented by the unit. This problem is increased in certain units where the edges of objects 0 are gripped by one or a plurality of tabs 14 on the belt to hold them.

It could have been devised to use a conveyor mat to place the objects at the center of this mat, thus avoiding for them to be caught into the lateral grooves. However, this does not solve the issue of the positioning of the objects on the mat. Indeed, for reasons of positioning accuracy linked to the unit using the conveyor (for example, an electronic board optical inspection unit), the positioning of the boards on the mat should be accurate. Further, the use of a mat is, in most cases, incompatible with objects comprising raised areas at their lower surface resting on the mat, which is true for electronic boards comprising components on both their surfaces.

FIG. 2 is a lateral view of an embodiment of a conveyor unit 1 comprising at least two belts 2 among which at least one drive belt driven by a motor 4. The belt is looped back on pulleys or rollers 5 and 6. In the example of FIG. 2, only two upper rollers 5 and two lower rollers 6 have been shown. However, their number may be different according, in particular, to the length of belt 2. Further, other patterns more complex than that illustrated in FIG. 2 may be provided. The driving of belt(s) 2 by means of motor 4 is generally performed by a guide system 42 driving one of the rollers, for example, lower roller 6. It is generally provided to drive the two belts on either side of the conveyed objects. Arrow f illustrates the direction of forward movement of belts 2. In the conveyor area (upper surface in FIG. 2), the belt is driven in a motion parallel to the conveying direction.

FIG. 3 is a partial perspective view illustrating an embodiment of a conveyor belt 2 and of rollers 5 and 6.

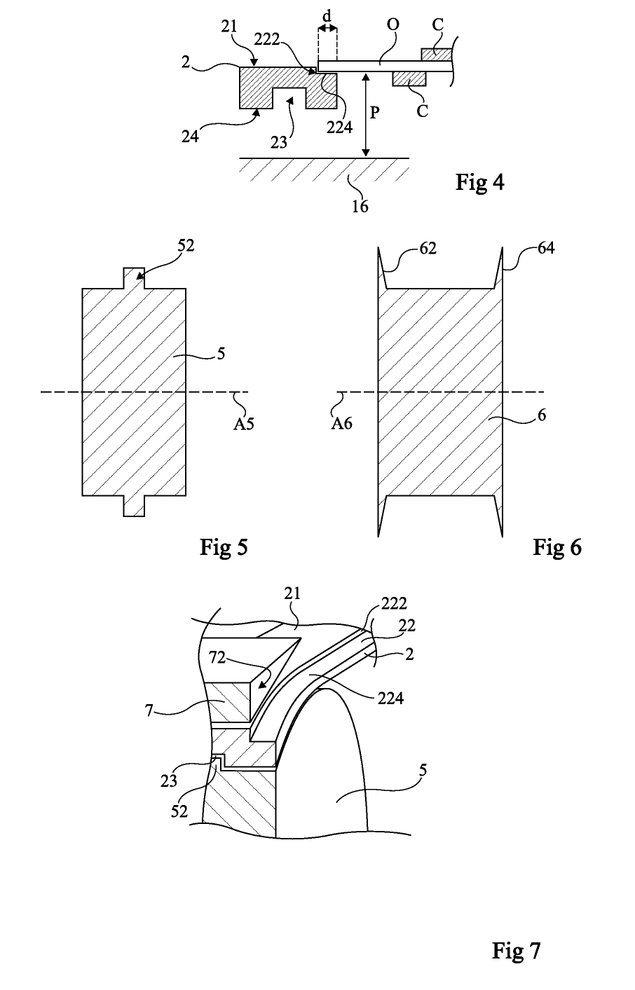

FIG. 4 is a cross-section view of belt 2 in situation with a board to be conveyed.

According to this embodiment, belt 2 has, in transverse cross-section, in its upper surface 21 and at the level of an edge (internal side of the equipment, that is, on the side of the object to be conveyed), a notch 22 defining a surface 224 for receiving an edge of object 0 recessed from upper surface 21. Shouldering 222 between surface 21 and surface 224 enables to position the electronic boards and ascertains their guiding whatever the board thickness. Any risk of jamming of the board in a possible groove for receiving the belt is thus avoided. Further, the friction of the electronic board against internal conveyor guides is avoided.

The belt is preferably inscribed, in transverse cross-section, within a rectangle. Shoulder 222 is approximately vertical and surface 224 is approximately horizontal (parallel to surface 21).

Electronic boards are generally designed with a distance d (FIG. 4) of a few millimeters, typically in the order of 3 mm, between the edge of the board and the first components. Notch 22 is preferably sized according to distance d.

Further, a depth P is preferably respected between the level of belts 2 in the unit and bottom 16 of the unit, or more generally the areas where devices are likely to be present under the objects, according to the thickness of the objects or, in the case of electronic boards, to the height of components likely to be present at the lower surface of the boards. For example, a depth P of a few tens of mm, for example, in the range from 5 to 10 cm, is provided.

According to a preferred embodiment, the guiding of the belt is performed by means of a groove 23, formed in lower surface 24 of the belt and cooperating with a rib 52 protruding from the periphery of at least upper rollers 5 of the unit.

FIG. 5 is a simplified cross-section view of an example of a roller 5.

FIG. 6 is a cross-section view of a simplified example of a roller 6.

The mechanisms for fastening the rollers to the rest of the unit have not been illustrated, only rotation axes A5 and A6 of these rollers have been symbolized in FIGS. 3, 5, and 6.

Rollers 6 intended to be on the return path of belt 2, that is, without for a board to be in contact therewith at the level of the roller, preferably comprise lateral flanges 62 and 64 for guiding belt 2.

However, such flanges at the level of rollers 5 in the upper portion would be detrimental since they would risk lifting board O or damaging components (C, FIG. 4) present at the lower surface of the board and located close to the edges. It could however be devised to increase the belt thickness. However, this would adversely affect the belt flexibility. This would further decrease the width of contact of the belt with the electronic board by the value of the flange thickness.

A guiding with a rib 52 and groove 23 thus is a preferred embodiment.

The dimensions of groove 23 are adapted to the dimensions of rib 52 of rollers 5. As a specific embodiment, the depth of groove 23 is smaller than half thickness E of belt 2 and its width is smaller than one third of the belt. The groove has been illustrated in central position of the belt, which is a preferred embodiment. It may however also be laterally offset. According to another variation, a plurality of parallel grooves 23 may be provided in the belt cross-section to cooperate with a plurality of ribs 52 of rollers 5.

As a variation, the belt may be housed in a groove of the type of groove 12 illustrated in FIG. 1A. Indeed, the presence of shoulder 22 avoids for board O to slide towards the bottom of groove 12.

FIG. 7 illustrates a detail of FIG. 3, at the end of the conveyor unit on the side of introduction of boards O. A part 7 placed on the planar portion of upper surface 21 of belt 2 is preferably provided. Such a part in tapered or nose shape, comprises a side 72, preferably aligned with shoulder 222. Thus, part 7 behaves as an input deflector for objects O, to guide them and helps them properly positioning in notch 22 on introduction thereof on the conveyor unit. It is thus avoided for a board to be laid on upper surface 21 of belt 2. According to a variation, not shown, side 72 of part 7 preferably extends lower than surface 22 of the belt to avoid any jamming of the belt under nose 7 on introduction of the board into the conveyor.

The above-described belt 2 and unit have many advantages.

On the one hand, this avoids for boards (or objects with thin edges) to be jammed in a guide groove (12, FIG. 1A) of belt 2.

Further, a proper positioning of the boards between the two opposite parallel belts of the conveyor unit is ascertained. The belt is thus used to laterally position the boards.

Further, by avoiding flanges at the level of rollers 5, the unit is made compatible with the presence of components at the lower surface of the electronic board.

It should be noted that the conveyor unit may comprise various board gripping, inlet positioning, and outlet collection devices which are not impacted by the implementation of the above-described embodiments.

Preferably, the nature of the belt has a sufficient friction coefficient to facilitate stops and starts of the conveyor unit without causing a shifting of electronic boards. As a specific example, a friction coefficient greater than 0.5, and preferably in the range from 0.5 to 1, preferably in the order of 0.8, is provided.

For example, the belts are made of polyurethane reinforced with a metal or composite fiber coated with a chloroprene, neoprene, or silicone layer.

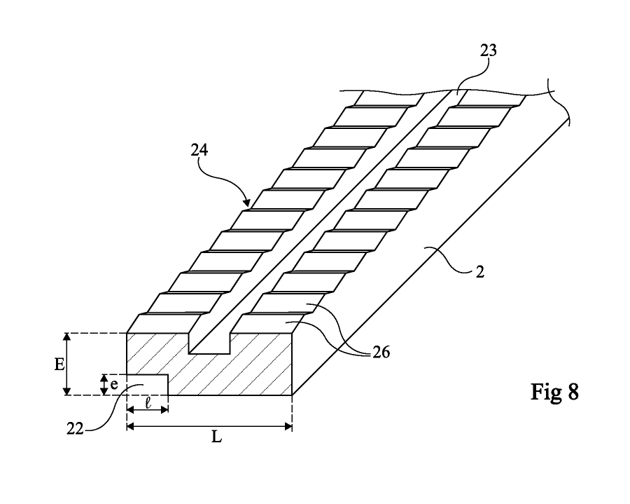

FIG. 8 is a partial cross-section perspective view of an alternative belt 2 according to which lower surface 24 of the belt comprises teeth 26. Such teeth make the belt driving easier. In this case, the depth of the groove is preferably equal to or slightly greater than the height of the toothing. The toothing takes part in the accurate positioning of the board in the conveyor since it suppresses the relative sliding between the belt driving system and the actual belts.

As a specific embodiment, not limited to the variation of FIG. 8:
length L of the belt is a few centimeters, for example, of a value in the range from 2 to 6 cm;
width l of notch 22 (of surface 224) is a few millimeters, for example, of a value in the range from 2 to 3 mm, corresponding to distance d between objects O;
the depth of notch 22 (height of shoulder 222) is a few millimeters, for example, of a value in the range from 1 to 5 mm; and
thickness E of the belt is in the order of 5 mm, for example, of a value in the range from 2 to 10 mm.

Various embodiments have been described. Various alterations, modifications, and improvements will occur to those skilled in the art. In particular, the practical implementation of the described embodiments and particularly the dimensions to be given to the belt and the settable or non-settable positions of the width of the conveyor unit depend on the application and are within the abilities of those skilled in the art based on the functional indications given hereabove.

1. A conveyor unit having at least one conveying belt comprising, in transverse cross-section, a notch defining a surface intended to receive an edge of an object to be conveyed, the external surface of the belt intended to receive the edge of the object being continuous, and this surface resting, by its surface opposite to the object to be conveyed, on a plurality of rollers of the unit, the belt being, in the conveying area, driven in a motion parallel to the conveying direction, said notch of the belt defining an approximately vertical shoulder and the conveyor further comprising at least one guide part of the objects to be conveyed, said guide part comprising a side aligned with said shoulder of the belt.

2. The unit of claim 1, wherein the width of said notch of the belt is selected according to the distance between the edge of the object to be conveyed and elements protruding from the object.

3. (canceled)

4. (canceled)

5. The unit of claim 1, wherein the friction coefficient is greater than 0.5.

6. The unit of claim 1, having a friction coefficient in the range from 0.5 to 1, and preferably equal to 0.8.

7. The unit of claim 1, comprising, at its lower surface, drive teeth.

8. The unit of claim 1, further comprising, at its lower surface, in transverse cross-section, at least one groove.

9. The unit of claim 8, wherein said groove cooperates with a rib protruding from the periphery of one or a plurality of rollers.

10. The unit of claim 9, wherein said roller(s) have no flanges.

11. The unit of claim 8, comprising two parallel belts having opposite notches.

12. The unit of claim 1, intended to convey electronic boards.
